(19) United States
(12) Patent Application Publication
(10) Pub. No.: US 2016/0374209 A1
(43) Pub. Date: Dec. 22, 2016

(54) METHOD OF FABRICATING METAL NANOWIRE PATTERN

(71) Applicant: POSTECH ACADEMY - INDUSTRY FOUNDATION, Pohang-si (KR)

(72) Inventors: Tae-Woo Lee, Pohang-si (KR); Sung-Yong Min, Pohang-si (KR)

(21) Appl. No.: 15/153,724

(22) Filed: May 12, 2016

(30) Foreign Application Priority Data
Jun. 18, 2015 (KR) 10-2015-0086794
Aug. 20, 2015 (KR) 10-2015-0117193

(51) Int. Cl. H05K 3/12; H05K 1/09

(52) U.S. Cl. CPC H05K 3/1241; H05K 1/09

(57) ABSTRACT

Disclosed is a method of fabricating a metal nanowire pattern. The method of fabricating the metal nanowire pattern is characterized by, using an organic nanowire, which is fabricated by means of an electric field auxiliary robotic nozzle printer, as a template, forming a metal nanowire into a desired shape by plating a metal layer on the organic nanowire. Therefore, various metal nanowire patterns can be formed in a large area and applied to electrodes or electronic devices.

### CROSS-REFERENCE TO RELATED APPLICATIONS

This application claims priority to and the benefit of Korean Patent Application No. 10-2015-0086794, filed on Jun. 18, 2015 and Korean Patent Application No. 10-2015-0117193, filed on Aug. 20, 2015, the disclosures of which are incorporated herein by reference in their entireties.

### BACKGROUND

1. Field of the Invention

The present invention relates to a method of fabricating a metal nanowire pattern, and more particularly, to a method of fabricating a large-area metal nanowire pattern based on a low-temperature process using a nano-template.

2. Discussion of Related Art

In the future information society (ubiquitous computer use area) in which information is accessible anywhere and anytime, the amount of information, which people encounter or process, will be greatly increased by “wearable computers” and “flexible displays”. In addition, as communication channels among people become more varied, the accomplishment of broad and close globalization is anticipated. Interest in nano-scale electronic devices has been increased with increasing need for much smaller electronic devices having excellent performance. Accordingly, research to develop transparent electrodes or lines using metal nanowires is actively underway.

As a representative method of fabricating metal nanowires, there is a solution-phase synthesis method wherein dispersed nanowires are synthesized in a solution. Metal nanowires synthesized using the solution-phase synthesis method are transferred and arrayed onto a substrate to fabricate a transparent electrode and an electronic device using the same.

The process has the following problems:

1) Since a nanowire fabricated according to the process is dispersed in a solution, a process of transferring the nanowire onto a substrate is necessary to use the nanowire as an electrode or a line.

2) Since a nanowire fabricated through solution synthesis has a very short length, i.e., a length of several micrometers, and it is difficult to individually control the same, it is impossible to fabricate an electrode or a line using a single nanowire.

3) Since a metal nanowire, which is fabricated by a separate method such as electrospinning or ink-jet printing, instead of a solution synthesis method, requires a high-temperature heat treatment process at 300° C. or more or a vacuum process, it is difficult to fabricate the metal nanowire on a plastic substrate.

Therefore, there is a need for a method of fabricating a large-area metal nanowire pattern to exactly control a location and a direction without application of a heat treatment process or a vacuum process.

### RELATED ART DOCUMENT

### Non-Patent Document

Lee, J.-Y, Connor, S. T., Cui, Y & Peumans, P. Nano Lett. 8, 689-692 (2008)

### SUMMARY OF THE INVENTION

The present invention is directed to a method of fabricating a large-area metal nanowire pattern based on a low-temperature process using a nano-template.

According to an aspect of the present invention, there is provided a method of fabricating a metal nanowire pattern. The method of fabricating the metal nanowire pattern may include a step of preparing an organic polymer solution by dissolving an organic polymer in distilled water or an organic solvent; a step of forming an arrayed organic nanowire pattern by dropwise adding the organic polymer solution onto a substrate; a step of forming a metal precursor ion/organic polymer complex nanowire pattern by immersing the organic nanowire pattern in a metal precursor solution; a step of forming a metal particle/organic polymer complex nanowire pattern by reacting the metal precursor ion/organic polymer complex nanowire pattern with a reducing agent; and a step of forming a metal nanowire pattern by immersing the metal particle/organic polymer complex nanowire pattern in a metal precursor/reducing agent mixture.

In addition, the organic polymer may be selected from the group consisting of polyvinyl pyridine, polyvinyl alcohol, polyethylene oxide, polystyrene, polycaprolactone, polyacrylonitrile, poly(methyl methacrylate), polyimides, poly(vinylidene fluoride), polyaniline, polyvinyl chloride, nylon, poly(acrylic acid), poly(chlorostyrene), poly(dimethylsiloxane), poly(ether imide), poly(ether sulfone), poly(alkyl acrylate), poly(ethyl acrylate), poly(ethyl vinyl acetate), poly(vinylpyridine-co-styrene), poly(ethyl-co-vinyl acetate), poly(ethylene terephthalate), poly(lactic acid-co-glycolic acid), poly(methacrylic acid) salts, poly(methyl styrene), poly(styrene sulfonic acid) salts, poly(styrene sulfonyl fluoride), poly(styrene-co-acrylonitrile), poly(styrene-co-butadiene), poly(styrene-co-divinyl benzene), poly(vinyl acetate), polylactide, polyacrylamide, polybenzimidazole, polycarbonate, poly(dimethylsiloxane-co-polyethyleneoxide), poly(ether ether ketone), polyethylene, polyethyleneimine, polyisoprene, polypropylene, polysulfone, polyurethane, poly(vinylpyrrolidone), poly(phenylene vinylene), poly(vinyl carbazole) and combinations thereof.

In addition, in the step of preparing the organic polymer solution, the organic polymer may be dissolved at a concentration of 3% by weight to 40% by weight in distilled water or the organic solvent.

In addition, in the step of forming the arrayed organic nanowire pattern, the substrate or the nozzle may be moved while the organic polymer solution is discharged from a nozzle, to which voltage is applied and which is at a point perpendicularly 10 μm to 20 mm apart from the substrate, and is added dropwise onto the substrate, forming the arrayed organic nanowire pattern.

In addition, the metal precursor solution may be formed by dissolving a first metal precursor in distilled water or the organic solvent.

In addition, the first metal precursor may include at least one selected from the group consisting of a copper precursor, a titanium precursor, an aluminum precursor, a silver precursor, a platinum precursor, a nickel precursor, and a gold precursor.

In addition, the metal precursor solution may be prepared by dissolving the first metal precursor at a concentration of 0.01% by weight to 5% by weight in the distilled water or organic solvent.

In addition, the reducing agent may include at least one selected from the group consisting of hydrazine, hydroxylamine, hydrogen peroxide, hydroquinone, mercaptosuccinic acid, sodium citrate and sodium borohydride.

In addition, the metal precursor/reducing agent mixture may be formed by dissolving a second metal precursor and a reducing agent in distilled water or the organic solvent.

In addition, the second metal precursor may include at least one selected from the group consisting of a copper precursor, a titanium precursor, an aluminum precursor, a silver precursor, a platinum precursor, a nickel precursor, and a gold precursor.

In addition, in the metal precursor/reducing agent mixture, the second metal precursor and the reducing agent mixed in a mole ratio of 10:90 to 40:60 may be dissolved in a concentration of 0.01% by volume to 10% by volume in distilled water or the organic solvent.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a flowchart illustrating a method of fabricating a metal nanowire pattern according to an embodiment of the present invention;

FIG. 2 is an image illustrating an arrayed polyvinyl pyridine nanowire pattern;

FIG. 3 is a graph illustrating a diameter distribution of an arrayed polyvinyl pyridine nanowire;

FIG. 4 is an image illustrating a large-area gold nanowire array;

FIG. 5 is a graph illustrating a current-voltage characteristic of a gold nanowire; and

FIG. 6 is a schematic diagram illustrating an electric field auxiliary robotic nozzle printer.

### DETAILED DESCRIPTION OF EXEMPLARY EMBODIMENTS

Exemplary embodiments of the present invention will be described in detail below with reference to the accompanying drawings.

While the invention is susceptible to various modifications and alternative forms, specific embodiments thereof are shown by way of example in the drawings and will herein be described in detail. It should be understood, however, that there is no intent to limit the invention to the particular forms disclosed. On the contrary, the invention is to cover all modifications, equivalents, and alternatives falling within the spirit and scope of the invention as defined by the claims.

It will be understood that when an element such as a layer, region or substrate is referred to as being “on” another element, it can be directly on the other element or intervening elements may also be present.

It will be understood that, although the terms “first”, “second”, etc. may be used herein to describe various elements, components, regions, layers and/or sections, these elements, components, regions, layers and/or sections should not be limited by these terms.

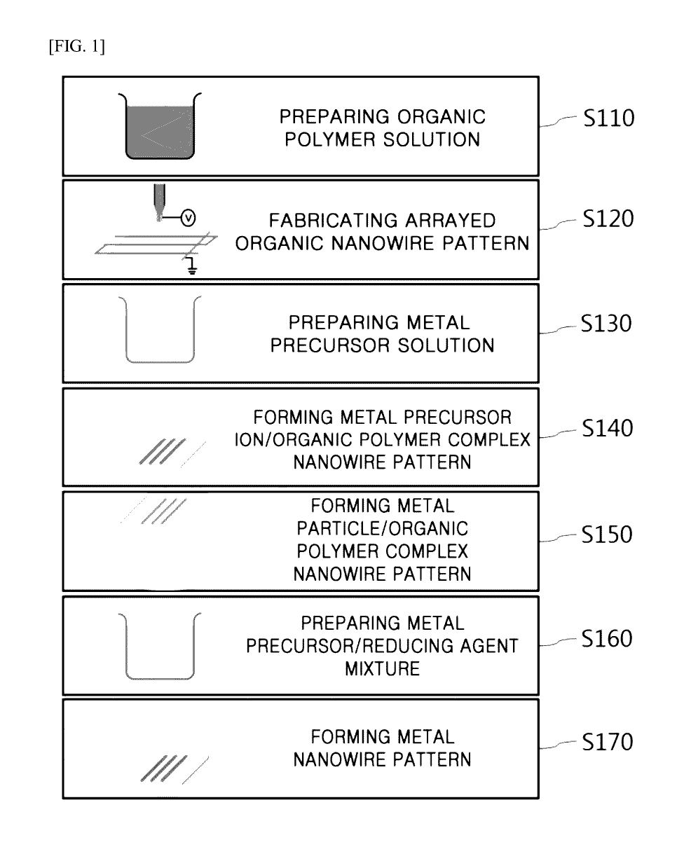

FIG. 1 is a flowchart illustrating a method of fabricating a metal nanowire pattern according to an embodiment of the present invention.

Referring to FIG. 1, a method of fabricating a metal nanowire pattern according to an embodiment of the present invention may include a step of preparing an organic polymer solution (S110), a step of fabricating an arrayed organic nanowire pattern (S120), step of preparing a metal precursor solution (S130), a step of forming a metal precursor ion/organic polymer complex nanowire pattern (S140), a step of forming a metal particle/organic polymer complex nanowire pattern (S150), a step of preparing a metal precursor/reducing agent mixture solution (S160), and a step of forming a metal nanowire pattern (S170).

First, an organic polymer solution is prepared (S110). Here, the organic polymer solution may be prepared by dissolving an organic polymer in distilled water or an organic solvent.

For example, the organic solvent may be selected from the group consisting of dichloroethylene, trichloroethylene, chloroform, chlorobenzene, dichlorobenzene, dichloromethane, styrene, dimethylformamide, dim ethyl sulfoxide, tetrahydrofuran, xylene, toluene, cyclohexene, 2-methoxyethanol, ethanolamine, acetonitrile, butyl alcohol, isopropyl alcohol, ethanol, methanol, acetone, and combinations thereof.

For example, the organic polymer may be selected from the group consisting of polyvinyl pyridine (P4VP), polyvinyl alcohol (PVA), polyethylene oxide (PEO), polystyrene (PS), polycaprolactone (PCL), polyacrylonitrile (PAN), poly(methyl methacrylate) (PMMA), polyimides, poly(vinylidene fluoride) (PVDF), polyaniline (PANT), polyvinyl chloride (PVC), nylon, poly(acrylic acid), poly(chlorostyrene), poly(dimethylsiloxane), poly(ether imide), poly(ether sulfone), poly(alkyl acrylate), poly(ethyl acrylate), poly(ethyl vinyl acetate), poly(vinylpyridine-co-styrene), poly(ethyl-co-vinyl acetate), poly(ethylene terephthalate), poly(lactic acid-co-glycolic acid), poly(methacrylic acid) salts, poly(methyl styrene), poly(styrene sulfonic acid) salts, poly(styrene sulfonyl fluoride), poly(styrene-co-acrylonitrile), poly(styrene-co-butadiene), poly(styrene-co-divinyl benzene), poly(vinyl acetate), polylactide, polyacrylamide, polybenzimidazole, polycarbonate, poly(dimethylsiloxane-co-polyethyleneoxide), poly(ether ether ketone), polyethylene, polyethyleneimine, polyisoprene, polypropylene, polysulfone, polyurethane, poly(vinylpyrrolidone), poly(phenylene vinylene), poly(vinyl carbazole), and combinations thereof.

In addition, in the step of preparing the organic polymer solution, the organic polymer is dissolved at a concentration of 3% by weight to 40% by weight in distilled water or an organic solvent.

Accordingly, when the organic polymer is dissolved at a concentration of less than 3% by weight, the viscosity of a solution is too low, whereby a nanowire pattern might not be normally formed in the subsequent process of forming the arrayed organic nanowire pattern. In addition, when the organic polymer is dissolved at a concentration of greater than 40% by weight, the viscosity of a solution is too high, whereby the diameter of the nanowire may become too thick or the organic polymer solution might not be discharged through a nozzle.

Next, an arrayed organic nanowire pattern is fabricated (S120). Here, the prepared arrayed organic nanowire pattern functions as a template for forming a metal nanowire pattern of the present invention.

For example, the arrayed organic nanowire pattern may be formed by dropwise adding the organic polymer solution onto a substrate.

As a more specific example, the substrate or the nozzle is moved while the organic polymer solution is discharged from the nozzle, to which voltage is applied and which is at a point perpendicularly 10 μm to 20 mm apart from the substrate, and is added dropwise onto the substrate, thereby forming the arrayed organic nanowire patter.

With increasing distance between a point, from which the organic polymer solution is dropwise added, and the substrate, nanowires are more rapidly arrayed in a horizontal direction while the organic polymer solution is dropwise added whereby the nanowires may be more easily bent. Accordingly, the nanowires are disturbed, whereby it is difficult to array nanowires in a desired direction or in parallel. However, according to the present invention, the organic polymer solution is dropwise added at a distance of 10 μm to 20 mm from the substrate, whereby bending of the nanowire may be inhibited and the nanowire may be arrayed in a desired direction.

Meanwhile, such an organic nanowire pattern may be formed by means of an electric field auxiliary robotic nozzle printer.

In the case that the organic nanowire pattern is formed by means of the electric field auxiliary robotic nozzle printer, the electric field auxiliary robotic nozzle printer may include:
i) a solution storage device for containing an organic polymer solution;
ii) a nozzle device for discharging a solution supplied from the solution storage device;
iii) a discharge controller, which is connected to the solution storage device, for discharging the organic polymer solution in the solution storage device at a constant rate;
iv) a voltage application device for applying high voltage to the nozzle;
v) a collector for fixing the substrate;
vi) a robot stage for moving the collector in a horizontal direction;
vii) a micro distance controller for moving the nozzle in a vertical direction;
viii) a base plate for supporting the collector;
ix) a housing enveloping an entire system including the solution storage device, the nozzle, the discharge controller, the voltage application device, the collector, the robot stage, the micro distance controller, and the base plate; and
x) a ventilator for discharging inner gases of the housing to the outside.

Here, the step of forming the arrayed organic nanowire pattern (S120) includes i) a step of supplying the organic polymer complex solution to the solution storage device; and ii) a step of discharging the organic polymer solution from the nozzle while high voltage is applied to the nozzle through the voltage application device of the electric field auxiliary robotic nozzle printer. When the organic polymer solution is discharged from the nozzle, the collector disposed on the substrate is moved in a horizontal direction.

In addition, a vertical distance between the collector and the nozzle is 10 μm to 20 mm.

In addition, the substrate includes a conductive material selected from the group including aluminum, copper, nickel, iron, chromium, titanium, zinc, lead, gold and silver, a semiconductor material selected from the group including silicon (Si), germanium (Ge) or gallium arsenide (GaAs), or an insulative material selected from the group including glass, a plastic film, or paper.

In addition, the diameter of a formed organic nanowire is 10 nm to 1000 nm.

Meanwhile, an electric field auxiliary robotic nozzle printer used to form the arrayed organic nanowire pattern is illustrated in FIG. 6 in more detail.

Next, a metal precursor solution is prepared (S130) and a metal precursor ion/organic polymer complex nanowire pattern is formed (S140).

For example, the metal precursor ion/organic polymer complex nanowire pattern may be formed by immersing the organic nanowire pattern in the metal precursor solution. For example, the organic nanowire pattern may be immersed in the metal precursor solution for five minutes to 60 minutes.

Here, the metal precursor solution may be formed by dissolving a first metal precursor in distilled water or an organic solvent.

For example, the organic solvent is selected from the group consisting of dichloroethylene, trichloroethylene, chloroform, chlorobenzene, dichlorobenzene, dichloromethane, styrene, dimethylformamide, dimethylsulfoxide, tetrahydrofuran, xylene, toluene, cyclohexene, 2-methoxyethanol, ethanolamine, acetonitrile, butyl alcohol, isopropyl alcohol, ethanol, methanol, acetone, and combinations thereof.

For example, the first metal precursor may include at least one selected from the group consisting of a copper precursor, a titanium precursor, an aluminum precursor, a silver precursor, a platinum precursor, a nickel precursor, and a gold precursor.

Here, the copper precursor may include at least one selected from the group consisting of copper acetate, copper acetate hydrate, copper acetylacetonate, copper i-butyrate, copper carbonate, copper chloride, copper chloride hydrate, copper ethylacetoacetate, copper 2-ethylhexanoate, copper fluoride, copper formate hydrate, copper gluconate, copper hexafluoroacetylacetonate, copper hexafluoroacetylacetonate hydrate, copper methoxide, copper neodecanoate, copper nitrate hydrate, copper nitrate, copper perchlorate hydrate, copper sulfate, copper sulfate hydrate, copper tartrate hydrate, copper trifluoroacetylacetonate, copper trifluoromethanesulfonate, and tetraamminecopper sulfate hydrate.

In addition, the titanium precursor may include at least one selected from the group consisting of titanium carbide, titanium chloride, titanium ethoxide, titanium fluoride, titanium hydride, titanium nitride, titanium isopropoxide, titanium propoxide, titanium methoxide, titanium oxyacetylacetonate, titanium 2-ethylhexyloxide, and titanium butoxide.

In addition, the an aluminum precursor may include at least one selected from the group consisting of aluminum chloride, aluminum fluoride, aluminum hexafluoroacetylacetonate, aluminum chloride hydrate, aluminum nitride, aluminum trifluoromethanesulfonate, triethylaluminum, aluminum acetylacetonate, aluminum hydroxide, aluminum lactate, aluminum nitrate hydrate, aluminum 2-ethylhexanoate, aluminum perchlorate hydrate, aluminum sulfate hydrate, aluminum ethoxide, aluminum carbide, aluminum sulfate, aluminum acetate, aluminum acetate hydrate, aluminum sulfide, aluminum hydroxide hydrate, aluminum phenoxide, aluminum fluoride hydrate, aluminum tributoxide, aluminum diacetate, aluminum diacetate hydroxide, and aluminum 2,4-pentanedionate.

In addition, the silver precursor may include at least one selected from the group consisting of silver hexafluorophosphate, silver neodecanoate, silver nitrate, silver trifluoromethanesulfonate, silver acetate, silver carbonate, silver chloride, silver perchlorate, silver tetrafluoroborate, silver trifluoroacetate, silver 2-ethylhexanoate, silver fluoride, silver perchlorate hydrate, silver lactate, silver acetylacetonate, silver methanesulfonate, silver heptafluorobutyrate, silver chlorate, silver pentafluoropropionate, and silver hydrogenfluoride.

In addition, the platinum precursor may include at least one selected from the group consisting of chloroplatinic acid hexahydrate, dihydrogen hexahydroxyplatinate, platinum acetylacetonate, platinum chloride, platinum chloride hydrate, platinum hexafluoroacetylacetonate, tetraammineplatinum chloride hydrate, tetraammineplatinum hydroxide hydrate, tetraammineplatinum nitrate, tetraammineplatinum tetrachloroplatinate, tetrachlorodiammine platinum, dichlorodiammine platinum, and diammineplatinum dichloride.

In addition, the nickel precursor may include at least one selected from the group consisting of hexaamminenickel chloride, nickel acetate, nickel acetate hydrate, nickel acetylacetonate, nickel acetylacetonate hydrate, nickel carbonyl, nickel chloride, nickel chloride hydrate, nickel fluoride, nickel fluoride hydrate, nickel hexafluoroacetylacetonate hydrate, nickel hexafluoroacetylacetonate, nickel hydroxide, nickel hydroxyacetate, nickel nitrate hydrate, nickel perchlorate hydrate, nickel perchlorate, nickel sulfate hydrate, nickel sulfate, nickel tetrafluoroborate hydrate, nickel tetrafluoroborate, nickel trifluoroacetylacetonate hydrate, nickel trifluoroacetylacetonate, nickel trifluoromethanesulfonate, nickel peroxide hydrate, nickel peroxide, nickel octanoate hydrate, nickel carbonate, nickel sulfamate hydrate, nickel sulfamate, and nickel carbonate hydroxide hydrate.

In addition, the gold precursor may include at least one selected from the group consisting of chlorocarbonylgold, hydrogen tetrachloroaurate, hydrogen tetrachloroaurate hydrate, chlorotriethylphosphinegold, chlorotrimethylphosphinegold, dimethyl(acetylacetonate)gold, gold(I) chloride, gold cyanide, gold sulfide, and gold chloride hydrate.

In addition, in the metal precursor solution, the first metal precursor is dissolved at a concentration of 0.01% by weight to 5% by weight in distilled water or the organic solvent.

Accordingly, when the first metal precursor is dissolved at a concentration of less than 0.01% by weight, it takes a long time until the organic nanowire pattern is formed as the metal precursor ion/organic polymer complex nanowire pattern. In addition, when the first metal precursor is dissolved at a concentration of greater than 5% by weight, the acidity of the metal precursor solution becomes too high, whereby the organic nanowire pattern is corroded.

Next, a metal particle/organic polymer complex nanowire pattern is formed (S150).

For example, the metal particle/organic polymer complex nanowire pattern may be formed by reacting the metal precursor ion/organic polymer complex nanowire pattern with the reducing agent.

For example, the reducing agent may include at least one selected from the group consisting of hydrazine (N₂H₄), hydroxylamine (NH₂OH), hydrogen peroxide (H₂O₂), hydroquinone, mercaptosuccinic acid, sodium citrate, and sodium borohydride.

Accordingly, metal particles are formed by reacting metal precursor ions with the reducing agent.

Next, a metal precursor/reducing agent mixture is prepared (S160) and a metal nanowire pattern is formed (S170).

For example, the metal nanowire pattern may be formed by immersing the metal particle/organic polymer complex nanowire pattern in the metal precursor/reducing agent mixture.

In addition, the metal precursor/reducing agent mixture may be formed by dissolving a second metal precursor and a reducing agent in distilled water or the organic solvent.

Here, the organic solvent is selected from the group consisting of dichloroethylene, trichloroethylene, chloroform, chlorobenzene, dichlorobenzene, dichloromethane, styrene, dimethylformamide, dimethylsulfoxide, tetrahydrofuran, xylene, toluene, cyclohexene, 2-methoxyethanol, ethanolamine, acetonitrile, butyl alcohol, isopropyl alcohol, ethanol, methanol, acetone, and combinations thereof.

Here, the second metal precursor may be the same as the aforementioned first metal precursor.

Here, the reducing agent may include at least one selected from the group consisting of hydrazine, hydroxylamine, hydrogen peroxide, hydroquinone, mercaptosuccinic acid, sodium citrate and sodium borohydride.

In addition, in the metal precursor/reducing agent mixture, the second metal precursor and the reducing agent mixed in a mole ratio of 10:90 to 40:60 are dissolved at a concentration of 0.01% by volume to 10% by volume in distilled water or the organic solvent.

Under the aforementioned conditions, the reduction and growth of metal particles occurs only near the nanowire pattern without corrosion of the metal particle/organic polymer complex nanowire pattern, and thus, selective metal nanowire formation is possible. Accordingly, the method according to the present invention exhibits improved effects, compared to existing metal plating methods in which thermal deposition, electroplating, etc. are used.

### Fabrication Example

Using a method of fabricating a metal nanowire array according to an embodiment of the present invention, a gold nanowire array was fabricated on a four-inch Si/SiO₂ (100 nm) wafer.

30% by weight of polyvinyl pyridine (poly(4-vinylpyridine)) was dissolved in a mixture of dimethylformamide and ethanol (mixed in ratio of 60:40% by weight), thus preparing a polyvinyl pyridine solution (organic polymer solution). The prepared polyvinyl pyridine solution was accommodated in a syringe of an electric field auxiliary robotic nozzle printer, and the polyvinyl pyridine solution was discharged from a nozzle while applying a voltage of about 1.6 kV to the nozzle. An arrayed polyvinyl pyridine nanowire pattern was formed on a substrate of a collector moved by a robot stage.

Here, the diameter of the used nozzle was 100 μm and a distance between the nozzle and the collector was 8 mm. A movement interval in a Y axis direction of the a robot stage was 100 μm and a movement distance in an X axis direction was 15 cm. The size of the collector was 20 cm×20 cm and the size of the substrate on the collector was 10 cm×10 cm. The substrate was a silicon (Si) wafer wherein a silicon oxide film (SiO₂) was coated to a thickness of 100 nm. The polyvinyl pyridine nanowire pattern was treated for five minutes in a UV/O3 cleaner.

Chloroauric acid (HAuCl₄) was dissolved in distilled water to prepare a chloroauric acid solution (metal precursor solution). The concentration of the prepared chloroauric acid solution was 0.5% by weight. The arrayed polyvinyl pyridine nanowire pattern was immersed in the chloroauric acid solution for 30 minutes and then removed from the chloroauric acid solution, followed by washing with water and drying. As a result, a gold precursor ion/polyvinyl pyridine complex nanowire pattern was fabricated.

Five drops of an aqueous hydrazine (N₂H₄) solution (10% by weight) were dropwise added onto a plastic container. Subsequently, the gold precursor ion/polyvinyl pyridine complex nanowire pattern was attached face-down to a lid of the plastic container and reduction was induced. After reduction for 15 minutes, the gold precursor ion/polyvinyl pyridine complex nanowire was reduced to a gold nanoparticle/polyvinyl pyridine complex nanowire.

0.1 ml of a hydrogen peroxide solution (30% by weight) and 0.2 ml of an aqueous chloroauric acid solution (0.5% by weight) were mixed with 9.7 ml of distilled water to prepare a gold precursor/hydrogen peroxide mixture (metal precursor/reducing agent mixture). The gold nanoparticle/polyvinyl pyridine complex nanowire pattern was immersed in the gold precursor/hydrogen peroxide mixture for five minutes and then removed therefrom, followed by washing with water and drying. As a result, a gold nanowire pattern was formed.

The diameter of the polyvinyl pyridine nanowire fabricated by means of an electric field auxiliary robotic nozzle printer was about 375 nm. The diameter of the gold nanowire fabricated on the substrate was 600 nm to 800 nm. The conductivity of the gold nanowire was analyzed. As a result, the gold nanowire had a low resistivity of 7.49±3.71 μΩ·cm.

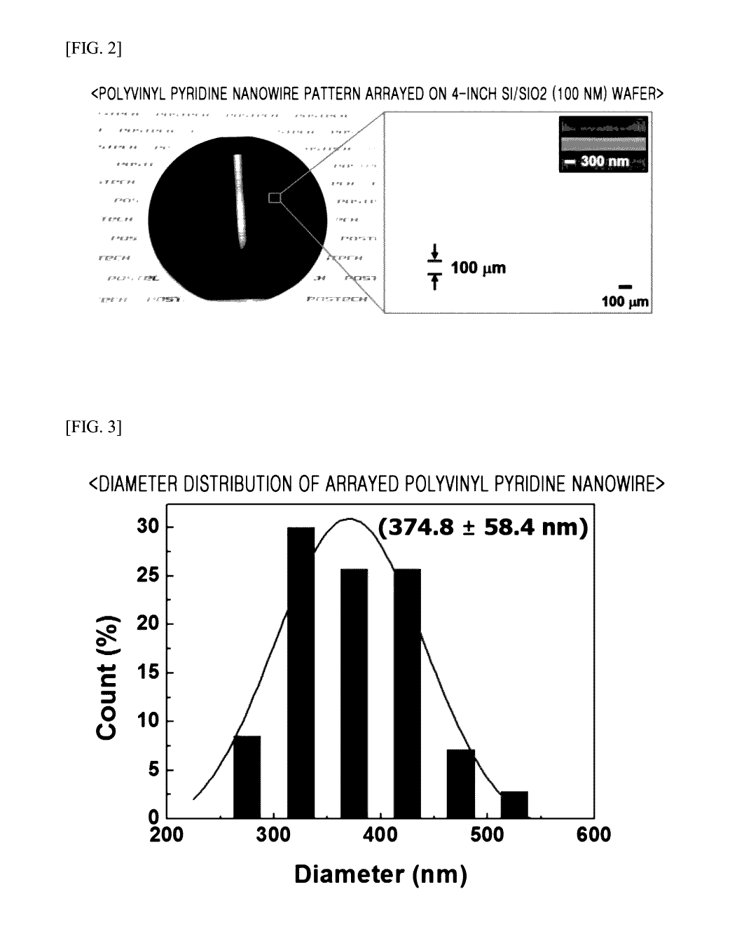

FIG. 2 is an image illustrating an arrayed polyvinyl pyridine nanowire pattern.

Referring to FIG. 2, it can be confirmed that the arrayed polyvinyl pyridine nanowire pattern is formed on a 4-inch Si/SiO₂ (100 nm) wafer.

FIG. 3 is a graph illustrating a diameter distribution of an arrayed polyvinyl pyridine nanowire.

Referring to FIG. 3, it can be confirmed that the diameter of the arrayed polyvinyl pyridine nanowire is mainly 374.8±58.4 nm.

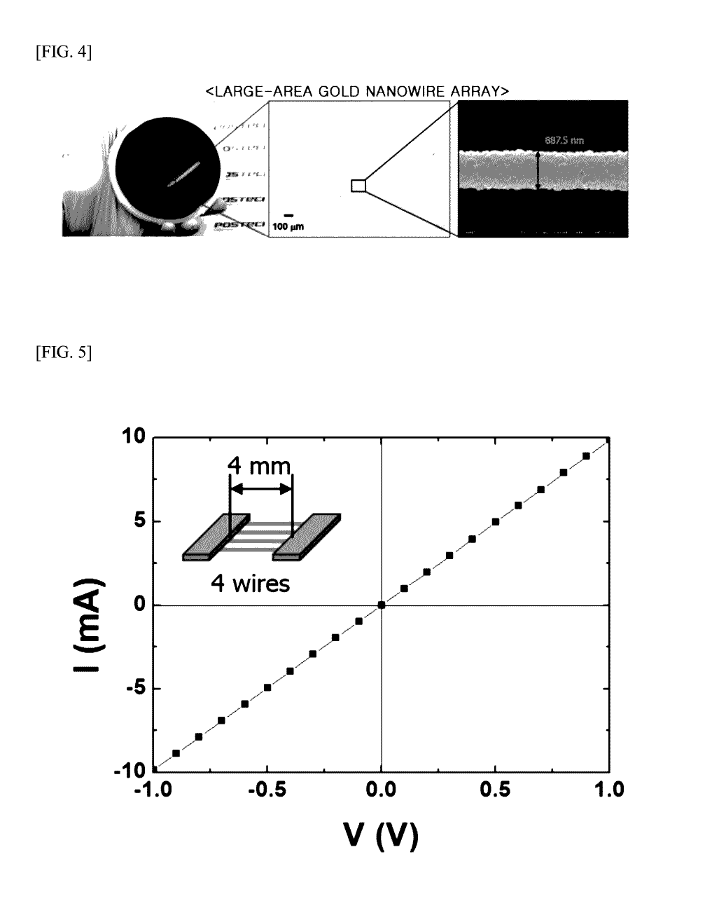

FIG. 4 is an image illustrating a large-area gold nanowire array.

Referring to FIG. 4, it can be confirmed that a large-area gold nanowire array is formed. Here, the diameter of the gold nanowire array is 887.5 nm.

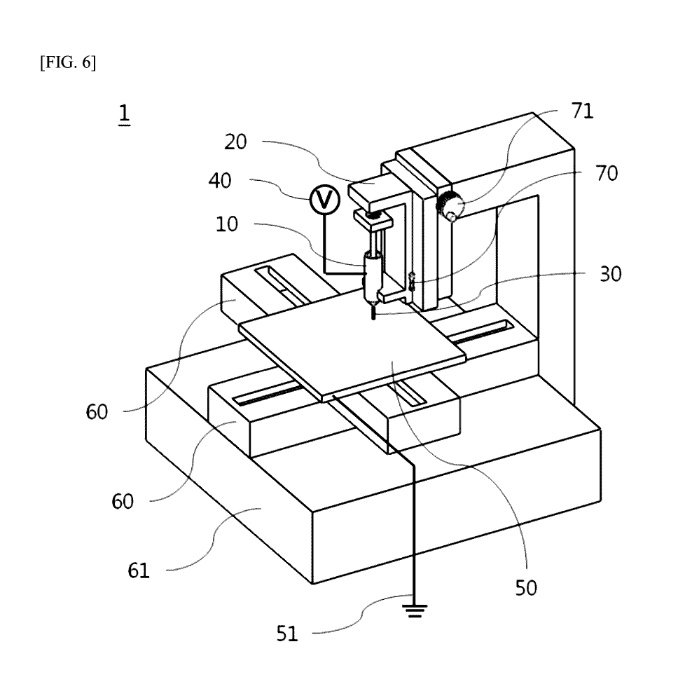

FIG. 5 is graph illustrating a current-voltage characteristic of a gold nanowire.

Referring to FIG. 5, four gold nanowires having a length of 4 mm are connected between two electrodes. Measured current-voltage characteristics thereof are illustrated in FIG. 5.

FIG. 6 is a schematic diagram illustrating an electric field auxiliary robotic nozzle printer.

The electric field auxiliary robotic nozzle printer illustrated in FIG. 6 may be used to fabricate the organic nanowire pattern according to the present invention.

Referring to FIG. 6, an electric field auxiliary robotic nozzle printer 1 particularly includes a solution storage device 10, a discharge controller 20, a nozzle 30, a voltage application device 40, a collector 50, a robot stage 60, a base plate 61, and a micro distance controller 70.

The solution storage device 10 stores the organic polymer solution, and supplies the solution to the nozzle 30 such that the nozzle 30 can discharge the solution.

Such a solution storage device 10 may take the form of a syringe. Such a solution storage device 10 may be made of plastic, glass, stainless steel, or the like.

A storage amount of such a solution storage device 10 may be selected within a range of about 1 μl to about 5,000 ml, and preferably, about 10 μl to about 50 ml.

In the case of the solution storage device 10 made of stainless steel, the solution storage device 10 includes a gas inlet (not shown) for injecting gas. Accordingly, the solution may be discharged to the outside of the solution storage device 10 using gas pressure.

Meanwhile, a plurality of solution storage devices 10 for forming an organic composite nanowire having a core-shell structure may be provided.

The discharge controller 20 applies pressure to the organic polymer solution in the solution storage device 10 so as to discharge the organic polymer solution in the solution storage device 10 via the nozzle 30 at a constant rate.

As such a discharge controller 20, a pump or a gas pressure regulator may be used.

The discharge controller 20 may control a discharge rate of the solution to be within a range of 1 nl/min to 50 ml/min.

When the plurality of the solution storage devices 10 are used, each of the solution storage devices 10 includes the discharge controller 20, and thus, each of the solution storage devices 10 may be independently operated.

In the case of the solution storage device 10 made of stainless steel, a gas pressure regulator (not shown) may be used as the discharge controller 20.

The organic polymer solution from the solution storage device 10 is supplied to the nozzle 30, followed by being discharged from the nozzle 30. The discharged solution may form drops at an end of the nozzle 30. The diameter of the nozzle 30 may be about 1 μm to about 1.5 mm.

The nozzle 30 may include a single nozzle, a dual-concentric nozzle, or a triple-concentric nozzle.

When the organic composite nanowire having a core-shell structure is formed, two or more organic solutions may be discharged by means of a dual-concentric or triple-concentric nozzle. In this case, two or three solution storage devices 10 may be connected to the dual-concentric or triple-concentric nozzle.

The voltage application device 40 may include a high voltage generator for applying high voltage to the nozzle 30.

The voltage application device 40 may be electrically connected to the nozzle 30, for example, through the solution storage device 10.

The voltage application device 40 may apply a voltage of about 0.1 kV to about 30 kV. An electric field is present between the nozzle 30, to which high voltage is applied by the voltage application device 40, and the collector 50. Drops formed at an end of the nozzle 30 form a Taylor cone by the electric fields and the nanowire is continuously formed at the end.

The nanowire formed from the solution discharged from the nozzle 30 is attached to the collector 50. The collector 50 has a plat shape and is movable in a horizontal plane by the robot stage 60 thereunder. The collector 50 is grounded such that the collector 50 has a relative grounding characteristic with respect to a high voltage that is applied to the nozzle 30.

The collector 50 is grounded by an element designated as a reference number 51. The collector 50 may be made of a conductive material, for example, metal, and may have a flatness degree of 0.5 μm to 10 μm (when a flatness degree of a completely horizontal surface is 0, the flatness degree represents a maximum error value from the surface).

The robot stage 60 is a means for moving the collector 50. The robot stage 60 is driven by a servo motor, thereby moving at a precise speed.

The robot stage 60 may be controlled, for example, so as to move in two directions, i.e., x and y axis directions, in a horizontal plane.

The robot stage 60 may be moved in intervals within a distance range of 100 nm or more and 100 cm or less. The distance range may be, for example, 10 μm or more and 20 cm or less.

A movement speed of the robot stage 60 may be 1 mm/min to 60,000 mm/min.

The robot stage 60 may be installed on a base plate 61 and may have a flatness of 0.5 μm to 5 μm. By the flatness of the base plate 61, a distance between the nozzle 30 and the collector 50 may be constantly adjusted.

The base plate 61 may adjust the accuracy of the organic nanowire pattern by suppressing vibration occurring upon operation of the robot stage.

The micro distance controller 70 adjusts a distance between the nozzle 30 and the collector 50. The micro distance controller 70 may adjust a distance between the nozzle 30 and the collector 50 by perpendicularly moving the solution storage device 10 and the nozzle 30.

The micro distance controller 70 may include a jog 71 and a micrometer 72. The jog 71 may be used to approximately adjust a distance of several millimeters or centimeters and the micrometer 72 may be used for fine adjustment to at least 10 μm.

The nozzle 30 may approach the collector 50 using the jog 71 and then a distance between the nozzle 30 and the collector 50 may be exactly adjusted using the micrometer 72.

A distance between the nozzle 30 and the collector 50 may be controlled to be within a range of 10 μm to 20 mm by the micro distance controller 70.

Meanwhile, an electric field auxiliary robotic nozzle printer 100 may be disposed inside the housing.

The housing may be made of a transparent material. The housing may be sealed and gas may be injected into the housing via a gas inlet (not shown). The injected gas may be nitrogen gas, dried air, etc. and the organic polymer solution capable of being easily oxidized by moisture may be stably maintained by the gas injection.

In addition, a ventilator and a lamp may be installed in the housing. The ventilator controls vapor pressure inside the housing to adjust an evaporation rate of a solvent upon formation of the nanowire. In robotic nozzle printing in which rapid evaporation of a solvent is required, evaporation of a solvent may be facilitated by adjusting the speed of the ventilator. The evaporation rate of the solvent affects morphological and electrical characteristics of the organic nanowire. When the evaporation rate of the solvent is too high, a solution is dried at the end of the nozzle before formation of the organic nanowire and thus the nozzle is blocked. When the evaporation rate of the solvent is too low, a solid organic nanowire is not formed and the organic nanowire is placed on the collector in a liquid state. In the case of the liquid-type organic polymer solution, a nanowire does not have a characteristic circular cross-section structure and thus the solution might not be used in fabrication of the metal nanowire.

As such, since the evaporation rate of the solvent affects nanowire formation, the ventilator plays an important role in forming the nanowire.

According to the present invention, the method of fabricating the metal nanowire pattern is characterized by, using an organic nanowire pattern, which is fabricated by means of an electric field auxiliary robotic nozzle printer, as a template, forming a metal nanowire into a desired shape by plating a metal layer on the organic nanowire.

Therefore, various metal nanowire patterns can be formed in a large area and applied to electrodes or electronic devices.

It will be understood that technical effects of the present invention are not limited to those referred above and other non-referred technical effects will be clearly understood by those skilled in the art from the above disclosure.

Meanwhile, embodiments of the present invention disclosed in the present specification and drawings are only provided to help understanding of the present invention and the present invention is not limited to the embodiments. It will be apparent to those skilled in the art that various modifications can be made to the above-described exemplary embodiments of the present invention without departing from the spirit or scope of the invention.

### DESCRIPTION OF SYMBOLS

10: Solution Storage Device
20: Discharge Controller
30: Nozzle
40: Voltage Application Device
50: Collector
51: Grounding Device
60: Robot Stage
61: Base Plate
70: Micro Distance Controller
71: Jog

What is claimed is:

1. A method of fabricating a metal nanowire pattern, the method comprising:
preparing an organic polymer solution by dissolving an organic polymer in distilled water or an organic solvent;
forming an arrayed organic nanowire pattern by dropwise adding the organic polymer solution onto a substrate;
forming a metal precursor ion/organic polymer complex nanowire pattern by immersing the organic nanowire pattern in a metal precursor solution;
forming a metal particle/organic polymer complex nanowire pattern by reacting the metal precursor ion/organic polymer complex nanowire pattern with a reducing agent; and
forming a metal nanowire pattern by immersing the metal particle/organic polymer complex nanowire pattern in a metal precursor/reducing agent mixture.

2. The method according to claim 1, wherein the organic polymer is selected from the group consisting of polyvinyl pyridine, polyvinyl alcohol, polyethylene oxide, polystyrene, polycaprolactone, polyacrylonitrile, poly(methyl methacrylate), polyimides, poly(vinylidene fluoride), polyaniline, polyvinyl chloride, nylon, poly(acrylic acid), poly(chlorostyrene), poly(dimethylsiloxane), poly(ether imide), poly(ether sulfone), poly(alkyl acrylate), poly(ethyl acrylate), poly(ethyl vinyl acetate), poly(vinylpyridine-co-styrene), poly(ethyl-co-vinyl acetate), poly(ethylene terephthalate), poly(lactic acid-co-glycolic acid), poly(methacrylic acid) salts, poly(methyl styrene), poly(styrene sulfonic acid) salts, poly(styrene sulfonyl fluoride), poly(styrene-co-acrylonitrile), poly(styrene-co-butadiene), poly(styrene-co-divinyl benzene), poly(vinyl acetate), polylactide, polyacrylamide, polybenzimidazole, polycarbonate, poly(dimethylsiloxane-co-polyethyleneoxide), poly(ether ether ketone), polyethylene, polyethyleneimine, polyisoprene, polypropylene, polysulfone, polyurethane, poly(vinylpyrrolidone), poly(phenylene vinylene), poly(vinyl carbazole) and combinations thereof.

3. The method according to claim 1, wherein, in the preparing, the organic polymer is dissolved at a concentration of 3% by weight to 40% by weight in distilled water or the organic solvent.

4. The method according to claim 1, wherein, in the forming of the arrayed organic nanowire pattern, the substrate or the nozzle is moved while the organic polymer solution is discharged from the nozzle, to which voltage is applied and which is at a point perpendicularly 10 μm to 20 mm apart from the substrate, and is added dropwise onto the substrate, forming the arrayed organic nanowire pattern.

5. The method according to claim 1, wherein the metal precursor solution is formed by dissolving a first metal precursor in distilled water or the organic solvent.

6. The method according to claim 5, wherein the first metal precursor comprises at least one selected from the group consisting of a copper precursor, a titanium precursor, an aluminum precursor, a silver precursor, a platinum precursor, a nickel precursor, and a gold precursor.

7. The method according to claim 5, wherein the metal precursor solution is prepared by dissolving the first metal precursor at a concentration of 0.01% by weight to 5% by weight in the distilled water or organic solvent.

8. The method according to claim 1, wherein the reducing agent comprises at least one selected from the group consisting of hydrazine, hydroxylamine, hydrogen peroxide, hydroquinone, mercaptosuccinic acid, sodium citrate and sodium borohydride.

9. The method according to claim 1, wherein the metal precursor/reducing agent mixture is formed by dissolving a second metal precursor and a reducing agent in distilled water or the organic solvent.

10. The method according to claim 9, wherein the second metal precursor comprises at least one selected from the group consisting of a copper precursor, a titanium precursor, an aluminum precursor, a silver precursor, a platinum precursor, a nickel precursor, and a gold precursor.

11. The method according to claim 9, wherein, in the metal precursor/reducing agent mixture, the second metal precursor and the reducing agent mixed in a mole ratio of 10:90 to 40:60 are dissolved at a concentration of 0.01% by volume to 10% by volume in distilled water or the organic solvent.
